(19) United States
(12) Patent Application Publication
(10) Pub. No.: US 2025/0164410 A1
(43) Pub. Date: May 22, 2025

(54) OPTICAL METROLOGY

(71) Applicant: Tokyo Electron Limited, Tokyo (JP)

(72) Inventors: Holger Tuitje, Fremont, CA (US); Xinkang Tian, Fremont, CA (US); Ching Ling Meng, Sunnyvale, CA (US)

(21) Appl. No.: 18/517,486

(22) Filed: Nov. 22, 2023

(51) Int. Cl. G01N 21/95; G01N 21/93; G01N 21/956; H01L 21/66

(52) U.S. Cl. CPC G01N 21/9501; G01N 21/93; G01N 21/956; H01L 22/24; G01N 2201/0423; G01N 2201/063; G01N 2201/0648; G01N 2201/068; G01N 2201/12769

(57) ABSTRACT

A method for monitoring a plurality of process chambers, the method includes generating an optical beam at a light source. The method further includes dividing the optical beam into a plurality of light beams. The method further includes providing the plurality of light beams to the plurality of process chambers. And the method further includes measuring the plurality of light beams after being reflected within the plurality of process chambers.

### TECHNICAL FIELD

The present invention relates to the field of semiconductor manufacturing and, more specifically, to optical metrology.

### BACKGROUND

Etching processes are frequently employed in conjunction with photolithography during the manufacturing of various electronic components such as semiconductor devices, liquid crystal displays (LCDs), light-emitting diodes (LEDs), and certain photovoltaic (PV) devices.

In many instances, particularly in the production of semiconductor devices, etching is carried out on an upper material layer overlaying a second material layer. It is crucial for this etching process to terminate precisely once it has created an opening or pattern in the upper material layer, without affecting the underlying second material layer. Precise control of the etching duration is essential to achieve either a precise halt at the upper material layer's interface or to attain exact vertical dimensions for the etched features.

To effectively control the etching process, various methods are employed. Some rely on analyzing the chemical composition of gases within the etching chamber to determine the progression of the process, especially when transitioning to a different chemical composition in the underlying material layer. Alternatively, in-situ optical metrology devices, such as optical sensors, can directly measure the etched top layer throughout the process. These sensors provide real-time feedback to ensure that the etching process stops precisely once a specific vertical feature is achieved (i.e., an end-point is detected).

For instance, in a typical application involving spacers, an in-situ optical sensor monitors film thickness, aiming to halt anisotropic oxide etching just a few nanometers before reaching the desired depth, and then transitioning to isotropic etching to achieve the ideal spacer profile. Additionally, these in-situ optical metrology devices can continuously measure films and etched features in real-time, providing valuable information about structure sizes. This information is used not only to control the ongoing etching process but also to adjust subsequent processes, especially when dealing with dimensions that deviate from specifications.

### SUMMARY

In accordance with an embodiment of the present invention, a method for monitoring a plurality of process chambers, the method includes generating an optical beam at a light source. The method further includes dividing the optical beam into a plurality of light beams. The method further includes providing the plurality of light beams to the plurality of process chambers. And the method further includes measuring the plurality of light beams after being reflected within the plurality of process chambers.

A method includes dividing an optical beam into a plurality of light beams. The method further includes transmitting the plurality of light beams through a plurality of light adjustment systems in to a plurality of process chambers. The method further includes reflecting one of the plurality of light beams off each of a plurality of calibration wafers to measure a property of each of the plurality of calibration wafers, each of the plurality of calibration wafers having a known surface reflectance. The method further includes determining, in a controller, whether the property of each of the plurality of calibration wafers is within a process window. And the method further includes adjusting one or more of the plurality of light adjustment systems based on the determining.

An optical metrology system includes a light divider optically coupled to a light source, the light divider having a single optical input and a plurality of optical outputs. The system further includes illumination systems optically coupled to the light divider, each of the illumination systems optically coupled to one of the optical outputs and each of the illumination systems being associated with one of a plurality of process chambers. And the system further includes collection systems, each of the collection systems being associated with one of the plurality of process chambers, each of the collection systems being optically coupled to one of the illumination systems through the associated process chamber.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a schematic diagram of an optical metrology system attached to an process chamber, in an embodiment;

FIG. 2A is a schematic diagram of the optical metrology system between the light source to the illumination systems in an embodiment using a common light source to illuminate multiple process chambers;

FIG. 2B is a schematic diagram of the elements of the optical metrology system between the light source to the illumination systems in an embodiment using a common light source to illuminate multiple process chambers;

FIG. 2C is a schematic diagram of the elements of the optical metrology system between the light source to the illumination systems in an embodiment using a common light source to illuminate multiple process chambers;

FIGS. 3A-3B are schematic diagrams of an illumination system of the optical metrology system in two different embodiments;

FIG. 4 is an illustration of an illuminated area on the surface of a substrate produced by a light beam from an illumination system in an embodiment;

FIGS. 5A-5B are schematic diagrams of a collection system of the optical metrology system in two different embodiments;

FIG. 6 illustrates a schematic diagram of the optical metrology system in an embodiment including a single spectrometer;

FIG. 7 is a flowchart of an optical metrology etch monitoring method for a plurality of substrates loaded in a plurality of process chambers in an embodiment; and

FIG. 8 is a flowchart of a method of calibrating an optical metrology system to simultaneously monitor a plurality of substrates being etched in a plurality of process chambers in accordance with an embodiment.

### DETAILED DESCRIPTION OF ILLUSTRATIVE EMBODIMENTS

Optical metrology devices have revolutionized real-time monitoring capabilities in etch processes. They have also helped enable smaller dimension features to be etched in semiconductor manufacturing processes by improving end-point detection. Though optical metrology systems have alleviated issues in semiconductor manufacturing, they have their own challenges, as well.

One difficulty faced by current optical metrology systems is the variation in intensity of the light beam produced by a light source over time. Such variation may occur for a number of reasons, but a significant contribution comes from the fogging of the access windows into the process chambers caused by the build-up of residue on the windows from prolonged exposure to etching. On the other hand, increasing the sophistication of the illumination system will result in increased manufacturing costs. As a result of these issues, the inventors believe an optical metrology system may be advantageous if such a system can account for changes in intensity without significantly increasing costs associated with purchasing multiple light source devices.

Accordingly, in various embodiments, this disclosure presents an optical metrology system for monitoring a plurality of etch processes in a plurality of process chambers simultaneously using a single light source. In various embodiments, the disclosure further details a method for monitoring the plurality of etch processes for end-point detection or modifying the corresponding etch process. In various embodiments, this disclosure also presents a calibration method for calibrating the optical metrology system by using a plurality of calibration wafers disposed in the plurality of process chambers. Thus, multiple process chambers can be centrally controlled and monitored, which would advantageously reduce manufacturing costs.

The optical metrology system discussed in various embodiments of this disclosure includes a plurality of filter wheels (such as a neutral density filter) that may be used to adjust intensities of light beams produced by the light source, which may be used to ameliorate changes in intensity. And, by enabling monitoring of the plurality of process chambers with a single light source, the optical metrology system of this disclosure reduces costs attributed to expensive light sources of optical metrology systems currently on the market.

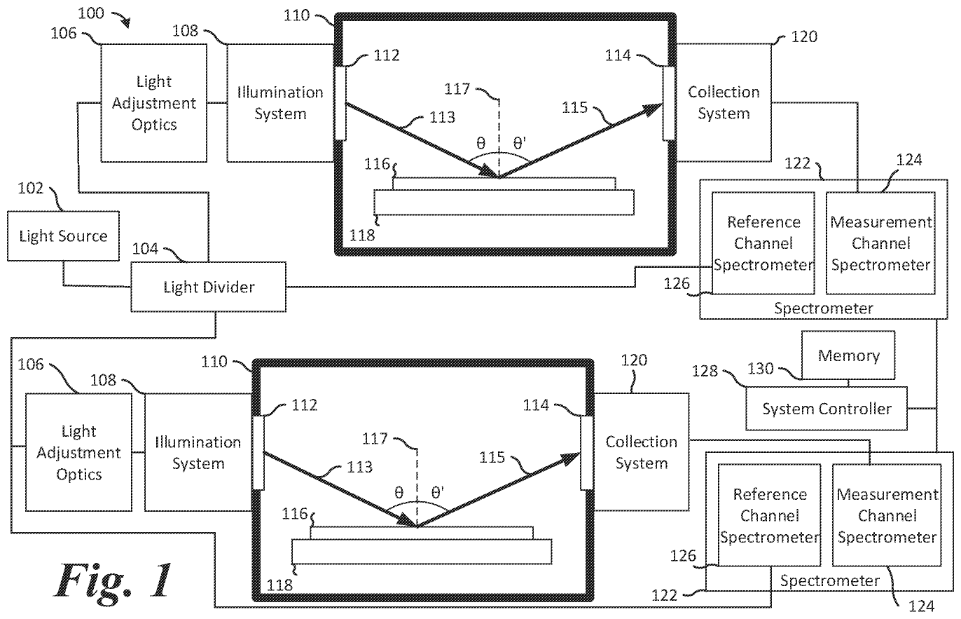

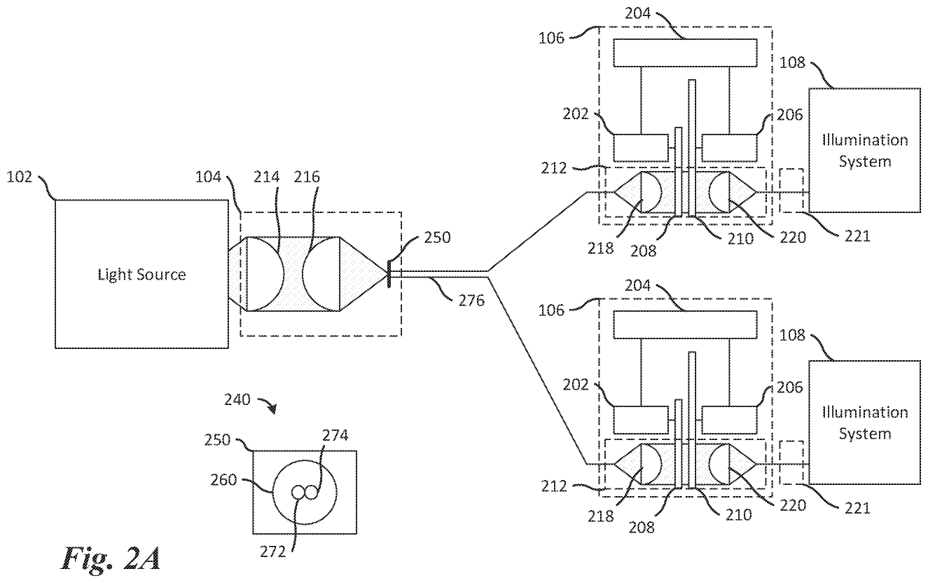

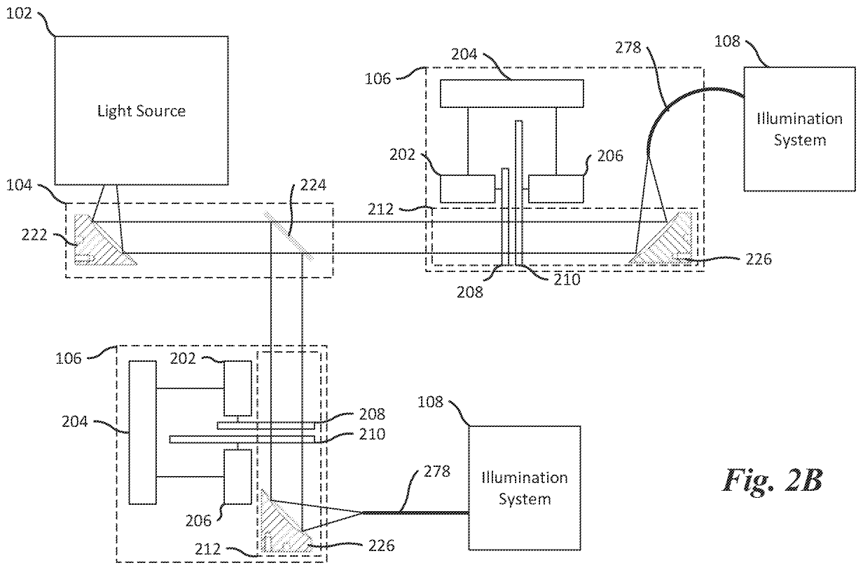

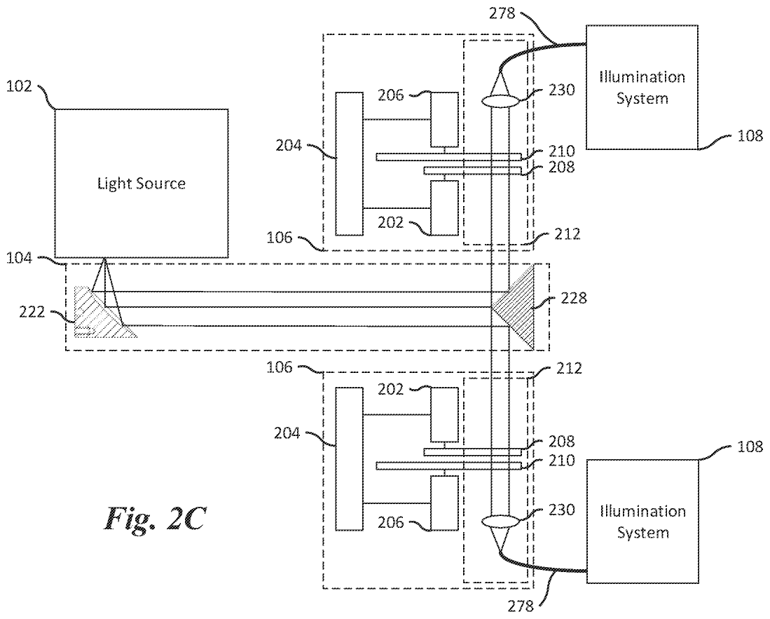

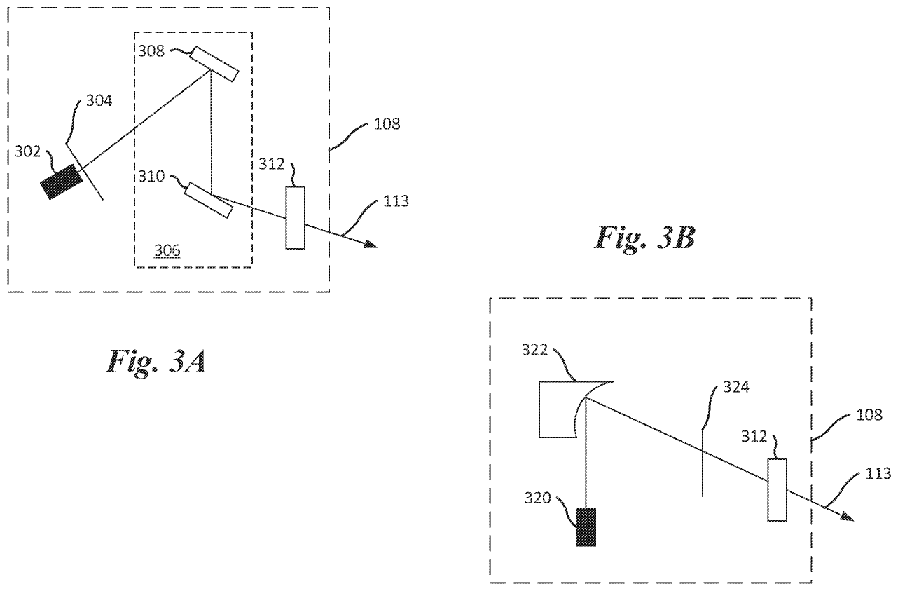

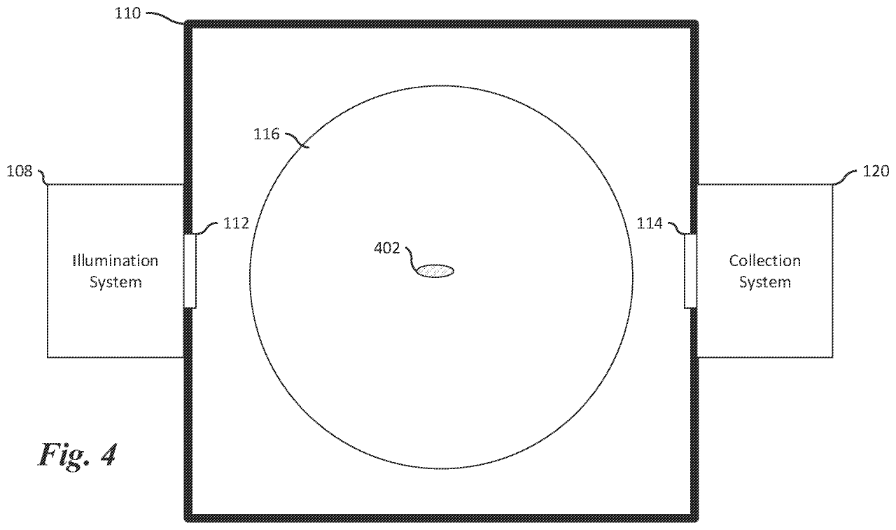

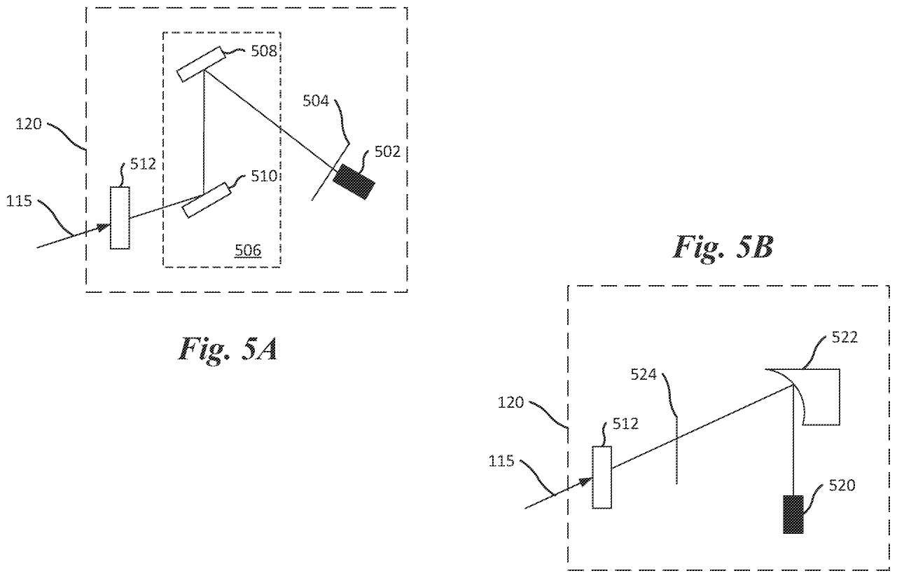

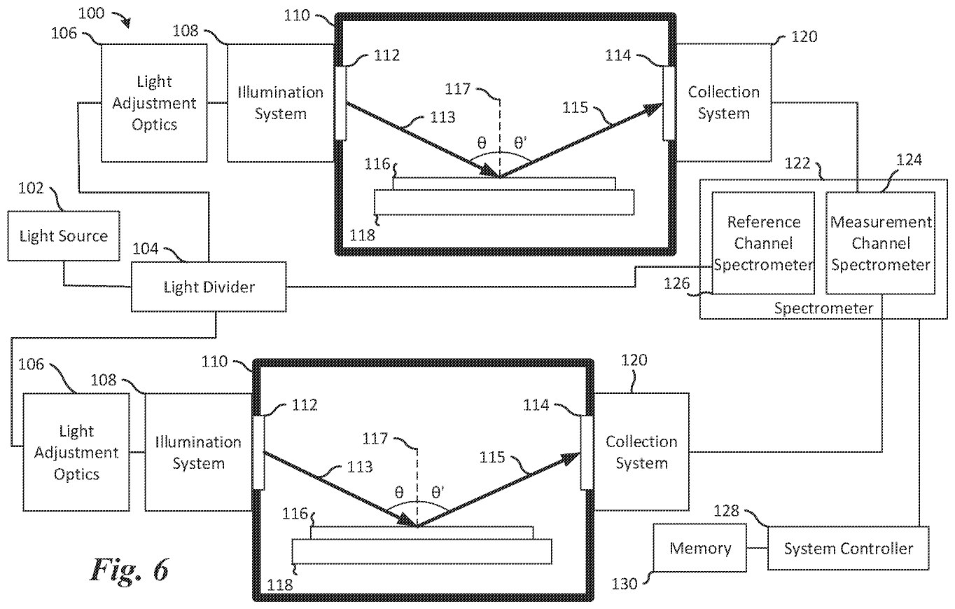

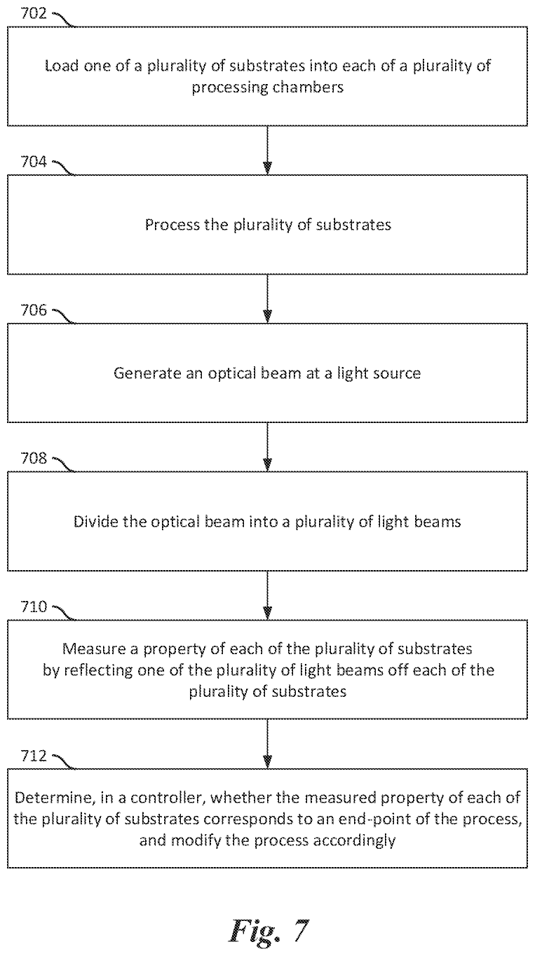

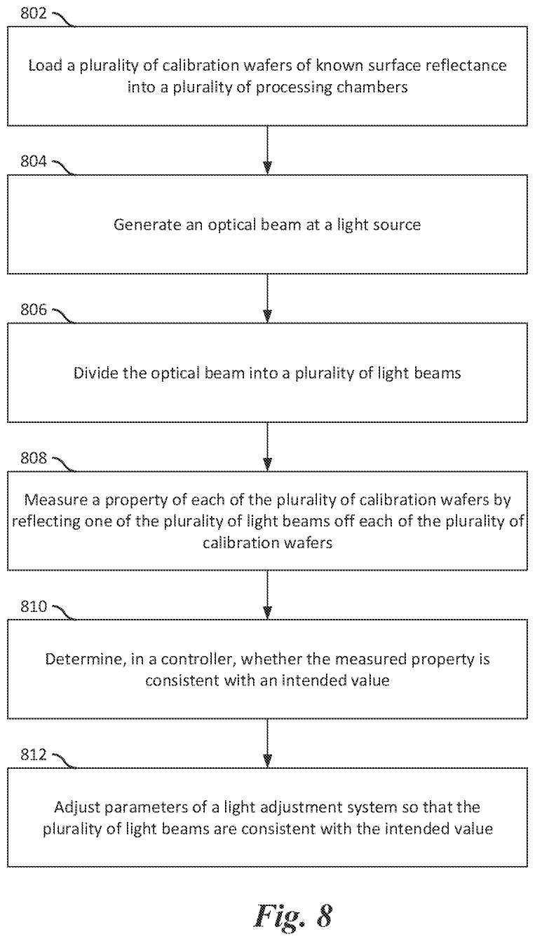

This disclosure begins with a schematic diagram of an embodiment optical metrology system which may be used with a plurality of process chambers using a single light source in FIG. 1, and an alternate embodiment is described in FIG. 6. Different systems of using a common single light source to illuminate a plurality of process chambers will be described using FIGS. 2A-2C. After the light beam from the light source is split to the plurality of process chambers, the split light beams may be polarized and directed by the plurality of illumination systems. An embodiment illumination system is illustrated in the schematic diagram of FIG. 3A. FIG. 3B is another embodiment of an illumination system that may be used in the optical metrology system of this disclosure. The illumination system outputs an incident light beam inside the process chamber to produce an illuminated area on the surface of a substrate within the process chamber, where an example illuminated area is illustrated in FIG. 4. The incident light beam reflects off of the surface of the substrate producing a reflected light beam, and the reflected light beam is collected by a collection system, such as the embodiment collection system illustrated as the schematic diagram of FIG. 5A, or the other embodiment of the collection system illustrated in FIG. 5B. A method of monitoring a plurality of etch processes simultaneously will be described using a flowchart of FIG. 7, and a method of calibrating the corresponding optical metrology system described using FIG. 8.

FIG. 1 shows a schematic diagram of an optical metrology system 100 attached to a plurality of process chambers 110 in an embodiment. The optical metrology system 100 illustrated in FIG. 1 may be used to simultaneously monitor a set of etch processes in the plurality of process chambers, and stop the individual etch process when the optical metrology system 100 determines that the etch process has reached an end-point. It should be noted that even though the illustration in FIG. 1 depicts two process chambers 110, the optical metrology system 100 may be deployed with many more process chambers in various other embodiments.

Referring now to FIG. 1, the optical metrology system 100 of this disclosure comprises a plurality of oblique incidence reflectometers, which have a high degree angle of incidence (AOI), as further described.

The optical metrology system 100 comprises a light source 102, a light divider 104, a plurality of light adjustment optics 106, a plurality of illumination systems 108, a plurality of collection systems 120, a plurality of spectrometers 122, a system controller 128, and a memory 130. In FIG. 1, the optical metrology system 100 supports the plurality of process chambers 110, where each process chamber 110 comprises the illumination window 112 attached to a side of the process chamber 110 with the collection window 114 attached to the opposite side of the process chamber 110. Each process chamber 110 may further comprise, during processing, a substrate 116 loaded onto a substrate holder 118. The substrate 116 may be any suitable substrate to be etched in the process chamber 110 that may be monitored using the optical metrology system 100 to detect an end-point for the etch process. In the illustrated embodiment of FIG. 1, each of the plurality of spectrometers 122 further comprise a reference channel spectrometer 126, and a measurement channel spectrometer 124. In an embodiment, a photodiode (not shown) or other similar detector may be used instead of the reference channel of spectrometer 122. Using a photodiode provides a reference light intensity signal integrated over all wavelengths, instead of spectrally resolved.

The optical metrology system 100 generates an optical beam from the light source 102 which may be coupled to the light divider 104 by a fiber optic cable. The light divider 104 comprises optical components that split the optical beam into a first portion of the optical beam and a second portion of the optical beam. The light divider 104 then splits the first portion of the optical beam into a plurality of optical reference beams where each is sent to the plurality of reference channel spectrometers 126 of the plurality of spectrometers 122 to measure properties of the optical reference beams. The second portion of the optical beam is further split into a plurality of optical beams by the light divider 104, which may be sent to the plurality of light adjustment optics 106 through various implementations (such as the embodiments illustrated in FIGS. 2A-2C) to adjust initial parameters of the plurality of optical beams.

Once the initial parameters of the plurality of optical beams have been adjusted using the light adjustment optics 106, the plurality of adjusted optical beams are sent to the plurality of illumination systems 108. The plurality of illumination systems 108 each comprise optical equipment for polarizing and directing each adjusted optical beam to output an incident light beam 113 through the illumination window 112 to the surface of the substrate 116 in the process chamber 110. In certain embodiments, the polarizers may be included in the light source 102. The incident light beam 113 is directed onto the surface of the substrate 116 at a high angle of incidence (θ) from a normal line 117 perpendicular to the plane of the surface of the substrate 116. In various embodiments, the high angle of incidence (θ) is larger than 60°. The incident light beam 113 reflects off of the surface of the substrate 116 to produce a reflected light beam 115 at a high angle of reflection (θ′), which passes through the collection window 114, and is received at the collection system 120. The law of reflection implies that the angle of incidence (θ) of the incident light beam 113 is equal to the angle of reflection (θ′), such that θ=θ′.

The collection system 120 comprises optical equipment for collecting and polarizing the reflected light beam 115. After the reflected light beam 115 is received at the collection system 120, the collection system 120 passes the reflected light beam 115 through a fiber optic coupling to the measurement channel spectrometer 124 of the spectrometer 122. The measurement channel spectrometer 124 measures properties of the reflected light beam to determine etch properties of the substrate 116. The initial properties of the optical reference beam and the properties of the reflected light beam 115, as measured by the spectrometer 122, are communicated to the system controller 128.

Each of the plurality of collection systems 120 provide the plurality of the reflected light beams 115 to the measurement channel spectrometer 124 of the plurality of spectrometers 122. The plurality of spectrometers 122 communicate the initial properties of the plurality of the optical reference beams and the properties of the plurality of reflected light beams 115 to the system controller 128. In an embodiment, the optical metrology system 100 is controlled with the system controller 128, which executes instructions stored in the memory 130 for simultaneously analyzing and determining etch properties of the plurality of substrates 116.

In the optical metrology system 100, the light source 102 forms the optical beam that illuminates substrate 116. In an embodiment, the light source 102 is a broadband light source such as a continuous wave (CW) broadband light source. For example, the light source 102 may be a laser driven plasma light source (LDLS) that provides light with very high brightness across a broad spectrum UV (ultraviolet)-VIS (visible)-NIR (near infrared) (i.e., 190 nm-2000 nm) with a long-life bulb (>9000 hours). In one embodiment, the light source 102 may be optically coupled to the light divider 104 through a fiber optic cable. The light divider 104 splits the optical beam to be sent to the reference channel spectrometer 126 of the spectrometer 122 and also to the light adjustment optics 106.

The light divider 104 splits the generated optical beam into 2n many optical beams, where n is an integer number greater than 0. In one embodiment, the optical beam is split into 2n many optical beams where n optical beams are sent through fiber optic cables coupled to the n reference channel spectrometers 126, and the remaining n optical beams are sent, by fiber optic cables, to n sets of light adjustment optics 106 coupled to n illumination systems 108. In various embodiments, the connections between the light divider 104 with the n sets of oblique reflectometers mounted to n process chambers 110 are made with optical fibers, or in combination with a set of optical components such as mirrors, prisms, and lenses. In one example, the light divider 104 divides the generated optical beam and uses parabolic mirrors to provide the beams to n sets of light adjustment optics 106 and minimize optical aberrations.

In the embodiment illustrated in FIG. 1, the light detector of the optical metrology system 100 is the spectrometer 122, which comprises the reference channel spectrometer 126 and the measurement channel spectrometer 124. In one embodiment, the spectrometer 122 may be a dual-channel broad-band high SNR (signal to noise ratio) spectrometer including a measurement channel spectrometer 124 (i.e., measurement spectrometer) for measuring the intensity of the reflected light beam 115 and a reference channel spectrometer 126 (i.e., reference spectrometer) for measuring the intensity of the optical reference beam. In another embodiment, the spectrometer 122 may be an ultra-broad band (UBB) spectrometer (i.e., 180 nm-1080 nm). The reference channel spectrometer 126 may be optically coupled to the light divider 104 through optical cable, and the measurement channel spectrometer 124 may be optically coupled to the collection system 120 through an optical cable.

The portion of the optical beam that is split to serve as the reference optical beam is subsequently directed to the reference channel spectrometer 126. The purpose of collecting the reference optical beam is to monitor the intensity of the reference optical beam so that any changes of the intensity of the incident light beam 113 can be accounted for in the measurement process. Such changes of intensity may occur as a result of drifting output power of light source 102, for example, where the drift can be wavelength-dependent. In an embodiment, the intensity of the reference optical beam may be measured by one or more photodiodes or the like. For example, a photodiode may detect the reference optical beam and provide a reference signal that is proportional to the intensity of the incident light beam 113 which is integrated across the entire illumination spectrum (e.g., UV-VIS-NIR).

In one embodiment, the intensity of the reference optical beam may be measured using a set of photodiodes. For example, the set of photodiodes may include three photodiodes, spanning UV-VIS-NIR wavelengths respectively. A filter may be installed in front of each photodiode of the set of photodiodes. For example, band pass filters may be used to monitor a portion of the spectrum (e.g., UV, VIS, NIR) for intensity variation of the light source 102. In one embodiment, the reference optical beam may be dispersed using a prism or grating into the set of photodiodes. Spectrally-dependent intensity variation of the light source 102 may thus be tracked and corrected for without the use of a reference spectrometer.

The optical metrology system 100 and associated methodologies can also use periodic measurements on a calibration wafer, such as a bare silicon wafer, to compensate for optical sensor or process chamber component's drifts, to compensate for changes in the illuminated area of the substrate 116 over time, and to calibrate the incident light beam 113 intensity using the light adjustment optics 106 as described later herein. A method for calibrating the optical metrology system 100 is described later in the detailed description of FIG. 8.

In an embodiment, the system controller 128 may be coupled to the plurality of spectrometers 122, and the memory 130. In other embodiments, the system controller 128 may be coupled to the light source 102, the plurality of light adjustment optics 106, the plurality of spectrometers 122, and the memory 130. The system controller 128 can acquire data from the light source 102, the plurality of light adjustment optics 106, and the plurality of spectrometers 122, and process the acquired data using instructions stored in the memory 130. The measured intensity of the reflected light beam 115 and the measured intensity of the reference optical beam are provided to the system controller 128. The system controller 128 processes the measured intensity of the reflected light beam 115 to suppress the light background and uses special algorithms such as machine learning methods to determine a layer of interest properties (e.g., feature dimension, optical properties) to control the etch process as described further below in the detailed description of FIG. 7. The system controller 128 can send instructions to the light source 102, the plurality of light adjustment optics 106, and the plurality of spectrometers 122 according to the processed data.

In various embodiments, the system controller 128 includes a processor (not shown) which performs the processes described in this disclosure. The processed data and instructions for controlling the optical metrology system 100 may be stored in the memory 130. The memory 130 may be any device suitable for storing the processed data and instructions, such as RAM, ROM, PROM, EPROM, EEPROM, hard disk, or any other information processing device with which the system controller 128 communicates, such as a server or computer.

The illumination window 112 provides access for the incident light beam 113 to pass from the illumination system 108 to the inside of the process chamber 110 to illuminate the surface of the substrate 116. The collection window 114 provides access for the reflected light beam 115 to pass from the surface of the substrate 116 inside the process chamber 110 to the collection system 120. Both the illumination window 112 and the collection window 114, depending on the configuration of the process chamber 110, may be quartz, fused silica, or sapphire. (i.e., in an embodiment where the process chamber 110 is a plasma processing chamber, the type of plasma source being used may adjust the composition of the windows). In various embodiments, the illumination window 112 and the collection window 114 may both be compound windows comprising multiple windows each. For the case where the process chamber 110 is a plasma processing chamber, the composition of the illumination window 112 and the collection window 114 depends on the application and how aggressive the chemistry of the plasma used in the process chamber 110, and depends on the wavelength of the transmitted light beams (both incident and reflected).

FIGS. 2A-2C are schematic diagrams of the elements of the optical metrology system 100 between light source 102 to the illumination systems 108, in various embodiments that use different optical components to split the optical beam from the light source 102 to the plurality of process chambers 110. FIG. 2A is an embodiment that uses a bifurcated fiber optic cable 276 to bring the optical beam from the light source 102 to the plurality of process chambers 110. FIG. 2B is an embodiment that uses a combination of a beam splitter and off-axis parabolic mirrors to bring the optical beam from the light source 102 to the plurality of process chambers 110. And FIG. 2C is an embodiment that uses a combination of parabolic mirrors and a knife edge right angle prism mirror to bring the optical beam from the light source 102 to the plurality of process chambers 110.

FIG. 2A is a schematic diagram of the elements of the optical metrology system 100 between light source 102 to the illumination systems 108, in an embodiment that uses a bifurcated fiber optic cable 276 and optics system to bring the optical beam from the light source 102 to the plurality of process chambers 110. In this embodiment, the light source 102 produces an optical beam that is passed through the light divider 104. The light divider 104 comprises a optics system such as the first lens 214 and second lens 216 which focuses the optical beam into a bifurcated fiber optic cable 276. The second lens 216 may focus the optical beam into a plane 250 where the bifurcated fiber optic cable 276 terminates. For example, the optical fibers may terminate at an optical coupler that is attached to the plane 250 of focus of the light divider 104.

A cross-sectional view 240 of the plane 250 where the bifurcated fiber optic cable 276 terminates is illustrated in FIG. 2A below the light divider 104. Each fiber optic cable (such as a first fiber optic cable 272 and a second fiber optic 274) in the bifurcated fiber optic cable 276 is illuminated by the illumination area 260 and receives a portion of the focused optical beam on the plane 250. Each of the fiber optic cables (both the first fiber optic cable 272 and the second fiber optic cable 274) transmit their received portions through optical coupling to one of the light adjustment optics 106.

In the embodiment illustrated in FIG. 2A, each set of light adjustment optics 106 comprise a shutter actuator 202 that operates a shutter 208, a stepper motor 206 that operates a filter wheel 210, and a control electronics 204 which couples to the shutter actuator 202 and the stepper motor 206. The light adjustment optics 106 further comprise a set of optics system 212, and in this embodiment, the optics system 212 comprises a first exposure lens 218 and a second exposure lens 220. In various embodiments, the optics system 212 may comprise lenses or mirrors, where mirrors advantageously do not lose transmission in the UV and VUV. The output optical beam from the light divider 104 passes through the bifurcated fiber optic cable 276, and the output is passed to the optics system 212 of the light adjustment optics 106. The output light beam passes through the first exposure lens 218, which spreads the light beam and passes it through the shutter 208 and filter wheel 210. If the light beam passes through both the shutter 208 and the filter wheel 210, the light beam is focused by the second exposure lens 220 so as to pass through a fiber optic coupling to the illumination system 108.

The shutter 208 may be rotated by the shutter actuator 202 which receives instructions from the control electronics 204. In an embodiment, the control electronics 204 is coupled to the system controller 128, which controls the rotation of the shutter 208 by the shutter actuator 202. In an embodiment, the shutter 208 may be used to modulate the incident light beam 113 in order to account for the background light measured by the measurement channel spectrometer 124 when the incident light beam 113 is blocked by the shutter 208. The background light may be any light which is not indicative of the reflected light beam 115 produced by the reflection of the incident light beam 113 (such as plasma light emissions for the case of a plasma processing chamber, or equipment light in the process chamber 110). For the case of a plurality of process chambers 110, the plurality of shutters 208 may be rotated to modulate when the plurality of spectrometers 122 send the measured properties of the plurality of reference optical beams and of reflected light beams 115 such that their measured spectral intensities are staggered in time (as opposed to sending the plurality of measured spectral intensities from the plurality of spectrometers 122 simultaneously).

The filter wheel 210 may be rotated to a corresponding angle that adjusts the intensity of the incident light beam 113 according to a prescribed calibration setting. For example, in an embodiment, the filter wheel 210 is set to 50°, which may only allow 20% of the intensity of the split optical beam through, thus diminishing the intensity of the split optical beam to be used in the illumination system 108. The filter wheel 210 coupled to the stepper motor 206 enables automatic light intensity adjustment for the incident light beam 113. The automatic light intensity adjustment of the filter wheel 210 position may use feedback (light level) from the measurement channel spectrometer 124 to change the filter wheel 210 position to result in an optimal light level, or adjust to a configurable light level limit (based on a bare silicon wafer or other reference wafer used for calibration). While the filter wheel 210 rotates, the measurement channel spectrometer 124 simultaneously collects spectra and the collected spectra may be used to find the position that results in the optimal light level or agrees with the configured limit. In an embodiment with a plurality of process chambers 110, each process chamber 110 may have a unique calibration setting that positions the filter wheel 210 at an angle that adjusts the intensity of the incident light beam 113 for that specific process chamber 110. The filter wheel 210 may be rotated to the prescribed angle by the stepper motor 206, which may be controlled by the control electronics 204. In an embodiment, the control electronics 204 is coupled to the system controller 128, which controls the rotation angle of the filter wheel 210 by controlling the stepper motor 206. In an embodiment, the filter wheel 210 may be a continuously variable neutral density (CVND) filter disc. In various embodiments, the filter wheel 210 may be either a discrete set of neutral density (ND) filters (arranged as sectors), or a CVND filter disc.

The control electronics 204 may be any composition of electronic components that can control the stepper motor 206 and the shutter actuator 202. In various embodiments, the plurality of control electronics 204 may be coupled to the system controller 128 and receive operational instructions to control the stepper motor 206 and the shutter actuator 202 to modulate and adjust the intensity of the plurality of incident light beams 113 according to the calibration settings for each particular process chamber 110. It should be noted that the embodiment illustrated in FIG. 2A, is not the only method of splitting the optical beam and passing the split optical beams through the plurality of light adjustment optics 106. Other example embodiments are illustrated in FIGS. 2B-2C.

FIG. 2B is a schematic diagram of the elements of the optical metrology system 100 between light source 102 to the illumination systems 108, in an embodiment that uses a combination of a beam splitter and off-axis parabolic mirrors to bring the light beam from the light source 102 to the plurality of process chambers 110. FIG. 2B may only differ from FIG. 2A by the components to split the initial light beam from the light source 102 and by the optics system 212 that direct the light beam after passing through the shutter 208 and the filter wheel 210. In FIG. 2B, the light divider 104 comprises a first off-axis parabolic mirror 222 that directs the optical beam to a beam splitter 224 that splits the optical beam to the different sets of light adjustment optics 106. The beam splitter 224, in various embodiments, is designed to allow the propagation of the reflected light beam 115 with minimum signal loss. The beam splitter 224, in various embodiments, may be a cube made from two triangular glass prisms, a half-silvered mirror, or a dichroic mirrored prism.

As opposed to FIG. 2A, the light adjustment optics 106 illustrated in this embodiment using FIG. 2B uses different components that comprise the optics system 212. In FIG. 2B, the optics system 212 comprises a second off-axis parabolic mirror 226, which focuses the adjusted optical beam. The adjusted optical beam is formed after the split optical beam passes through the shutter 208 and the filter wheel 210, and is sent through a fiber optic cable 278 to the illumination system 108.

In an embodiment, the first off-axis parabolic mirror 222 and the second off-axis parabolic mirror 226 are 90° off-axis parabolic mirrors. In one or more embodiments, the first off-axis parabolic mirror 222 and the second off-axis parabolic mirror 226 can be mirrors coated with high-reflectance coatings, such as aluminum, gold, or the like. In various embodiments, the first off-axis parabolic mirror 222 and the second off-axis parabolic mirror 226 are configured to direct light beams and minimize optical aberrations.

FIG. 2C is another schematic diagram of the elements of the optical metrology system 100 between light source 102 to the illumination systems 108, in an embodiment that uses a combination of off-axis parabolic mirrors and a knife edge right angle prism mirror to bring the light beam from the light source 102 to multiple process chambers 110. FIG. 2C may only differ from FIG. 2A by the components to split the optical beam from the light source 102 and by the optics system 212 that direct the optical beam after passing through the shutter 208 and the filter wheel 210. In FIG. 2C, the light divider 104 comprises a first off-axis parabolic mirror 222 that directs the optical beam to a knife edge right angle prism mirror 228, which splits the optical beam to the plurality of light adjustment optics 106.

As opposed to FIG. 2A, the light adjustment optics 106 in FIG. 2C may have different components for the optics system 212. In FIG. 2C, the optics system 212 comprise an exposure focusing lens 230 that couples the adjusted optical beam, formed after the optical beam passes through the shutter 208 and the filter wheel 210, and through an optical coupling to the illumination system 108. The exposure focusing lens 230 may be any type of lens that is appropriate for coupling the adjusted optical beam through a fiber optic cable 278 to the illumination system 108.

In an embodiment, the first off-axis parabolic mirror 222 is a 90° off-axis parabolic mirror. In various embodiments, the first off-axis parabolic mirror 222 can be a mirror coated with high-reflectance coatings, such as aluminum, gold, or the like. The first off-axis parabolic mirror 222 is configured to direct light beams and minimize optical aberrations.

The embodiments illustrated in FIGS. 2A-2C are illustrated as examples. In various other embodiments, the plurality of process chambers 110 may be on the order of tens of process chambers 110 where the oblique reflectometers share a single light source 102. In another embodiment, rather than a beam splitter, or bifurcated fiber optic cable, or knife edge right angle prism mirror, the light divider 104 may divide the optical beam into a plurality of optical beams by using an optical switch. The optical switch may be controlled by the system controller 128 to only illuminate certain process chambers 110 at a time, which would eliminate the need for a shutter 208 to stagger the plurality of measured spectral intensities.

While FIGS. 2A-2C do not depict the components in the light divider 104 that divide the optical beam from the light source into multiple reference optical beams for coupling to the plurality of reference channel spectrometers 126, these components are indeed present. The optical components that split the optical beam from the light source into a plurality of reference optical beams to be sent to the plurality of reference channel spectrometers 126 may be any configuration that accomplishes that task, such as beam splitters, or knife edge right angle prism mirrors.

After adjusting parameters of the plurality of optical beams (by passing them through the plurality of shutters 208 and the plurality of filter wheels 210 of the plurality of light adjustment optics 106), the plurality of adjusted optical beams are sent to the plurality of illumination systems 108.

The illumination systems 108 are described using the illustrations of FIGS. 3A-3B, below. FIG. 3A illustrates a schematic diagram of an embodiment of the illumination system 108, and FIG. 3B illustrates a schematic diagram of another embodiment of the illumination system 108, as an example.

FIG. 3A is a schematic diagram of the illumination system 108 of the optical metrology system 100, in an embodiment. The schematic diagram of FIG. 3A illustrates a typical implementation of the illumination system 108. The illumination system 108 comprises an illumination optics module 302, a pinhole 304, a reflective objective 306, and an illumination polarizer 312. The illumination polarizer 312 is optional.

The illumination system 108 takes in an adjusted optical beam passed from the light adjustment optics 106 at the illumination optics module 302. After passing through the illumination optics module 302, the adjusted optical beam passes through the pinhole 304, and then passes through the reflective objective 306. After the adjusted optical beam passes through the reflective objective 306, the adjusted optical beam passes through the optional illumination polarizer 312, and the illumination system 108 outputs the incident light beam 113 of an appropriate diameter and focus to achieve a certain illuminated area size to illuminate the surface of the substrate 116.

The illumination optics module 302 may be any form of optical coupling suitable for the illumination system 108. The illumination optics module 302 is intended to couple the illumination system 108 to the light adjustment optics 106 so that the adjusted optical beam sent from the light adjustment optics 106 may be received at the illumination system 108. In an embodiment, the illumination optics module 302 is a fiber optic coupling that couples the light adjustment optics 106 to the illumination system 108.

The illumination polarizer 312 is optional. In an embodiment where the illumination polarizer 312 is present, the illumination polarizer 312 imposes a linear polarization to the incident light beam 113 that reaches the substrate 116. The illumination polarizer 312 may be a Rochon Polarizer with high extinction ratio, large e- and o-ray separation, for example, a MgF₂ Rochon Polarizer, an Alpha-BBO Rochon Polarizer, or the like. Polarization of the incident light beam 113 increases the signal-to-noise ratio of the oblique reflectometer signal, and thereby improves measurement accuracy and improves sensitivity of feature dimension measurements compared to an un-polarized incident light beam 113. In an embodiment where the illumination polarizer 312 is not present, the incident light beam 113 is not polarized before being sent through the illumination window 112.

The reflective objective 306 may be any set of optical devices suitable for producing an incident light beam 113 of an appropriate diameter and focus to achieve a certain illuminated area size and shape to illuminate the surface of the substrate 116. The reflective objective 306 comprises a concave mirror 308 and a convex mirror 310 in the embodiment illustrated in FIG. 3A.

In an embodiment where the reflective objective 306 includes an aperture, the incident light beam 113 may be passed through an aperture that is located after the pinhole 304. The aperture may be modified to generate an illuminated area having different shapes (e.g., rectangular, square). Subtle modification to the aperture can be used to efficiently optimize the size and shape of the illuminated area on the substrate, for example based on the sizes and characteristics of the structures being measured. In another embodiment, the reflective objective 306 may comprise an off-axis parabolic mirror, such as the embodiment illustrated in FIG. 3B.

As an example, FIG. 3B is another embodiment of the illumination system 108. The illumination system 108 illustrated in FIG. 3B comprises an optical fiber 320, an off-axis parabolic mirror 322, a pupil 324, and the illumination polarizer 312 (which is optional). In embodiments using the illumination polarizer 312, the system may be configured for s- or p-polarization of the incident light beam 113. The difference between the embodiment illustrated in FIG. 3A and the embodiment illustrated in FIG. 3B is the components that the light beam passes between before being directed out of the illumination system 108. In the embodiment illustrated in FIG. 3B, the light beam passes from the optical fiber 320 to the off-axis parabolic mirror 322, and then passes through the pupil 324 to the optional illumination polarizer 312. And after passing through either the pupil 324, or the optional illumination polarizer 312 (depending on if the illumination polarizer 312 is being used) the incident light beam 113 is directed to the surface of the substrate 116 through the illumination window 112. In various embodiments, the illumination system 108 of FIG. 3B may also include an aperture as was described above.

As was stated above, the illumination system 108 polarizes (polarizing is optional) and directs the incident light beam 113 to illuminate a surface area of the substrate 116 according to a set of calibration settings for monitoring the etch process. In particular, the illumination system 108 directs the incident light beam 113 according to the calibration settings, such that the intended monitoring location of the substrate 116 is illuminated. An example of the illuminated area produced by the incident light beam 113 on the surface of the substrate 116 is illustrated in FIG. 4.

FIG. 4 is a schematic diagram of an illuminated area 402 produced by the incident light beam 113 on the surface of the substrate 116 that is being monitored for end-point detection by the optical metrology system 100 of this disclosure, in an embodiment. The size of each dimension of the illuminated area 402 may vary from 50 microns to 60 millimeters (mm) or more. In an embodiment, the illuminated area may be elliptical in shape covering an area of about 6 millimeters×34 millimeters. The illuminated area 402 illustrated in FIG. 4 is elliptical in shape due to the incident light beam 113 having a circular cross-sectional area and a highly oblique angle of incidence, θ.

As was described above, an aperture (not shown) of the illumination system 108 may be modified to generate the illuminated area 402 having different shapes (e.g., rectangular, square). Subtle modification to the aperture can be used to efficiently optimize the size and shape of the illuminated area 402 on the substrate 116, for example based on the sizes and characteristics of the structures being measured. For example, an elliptical aperture may be used to form an illuminated area 402 on the substrate 116 that is circular.

The embodiment illustrated in FIG. 4 has an elliptical illuminated area 402. In embodiments that use an elliptical illuminated area 402, the ratios of major and minor diameters of the ellipse are generally between 2 and 10, where higher values correspond with larger angles of incidence. The size of the illuminated area 402 may depend on the sizes and characteristics of structures being measured on the plurality of substrates 116 and may be adjustable to ensure good signal. Preferably, the size of the illuminated area 402 may be 1 mm×10 mm, 2 mm×20 mm, 3 mm×30 mm, or 5 mm×58 mm for embodiments with an angle of incidence, θ, of 85°, or 5 mm×11.5 mm, 6 mm×14 mm, 8 mm×18 mm for embodiments with an angle of incidence, θ, of 64°. The illuminated area 402 may cover multiple structures on the substrate 116. Consequently, detected optical properties (e.g., index of refraction) may represent an average of the features associated with the structures of the substrate 116.

After the incident light beam 113 reflects off of the surface of the substrate 116 (and produces the illuminated area 402 on the surface of the substrate 116), the reflected light beam 115 is collected by the collection system 120. FIG. 5A is a schematic diagram of the collection system 120 of the optical metrology system 100, in an embodiment. Each of the plurality of collection systems 120 comprise a collection polarizer 512, a second reflective objective 506, a second pinhole 504, and an optical fiber 502 that couples the collection system 120 to the measurement channel spectrometer 124.

The collection system 120 collects the reflected light beam 115 (after propagating through the collection window 114) through the collection polarizer 512. After, the reflected light beam 115 passes through the second reflective objective 506, and is then sent through the second pinhole 504 to the optical fiber 502 that couples the collection system 120 to the measurement channel spectrometer 124.

The reflected light beam passes through the collection polarizer 512. The collection polarizer 512 only allows p-polarized or s-polarized light reflected from the substrate 116 to be measured (depending on the configuration of the illumination system 108). The collection polarizer 512 may be any suitable polarizer that, in the illustrated configuration, would only allow p-polarized light reflected from the substrate 116 to pass through it, such as a Rochon prism.

After passing through the collection polarizer 512, the reflected light beam 115 passes through the second reflective objective 506. The second reflective objective 506 may be similar to the reflective objective 306. The second reflective objective 506 collects the reflected light beam 115, and may be composed of any suitable optical components appropriate for that task. In an embodiment, the second reflective objective 506 comprises a second convex mirror 510, and a second concave mirror 508.

After passing through the second reflective objective 506, the reflected light beam 115 is passed through the second pinhole 504. And after passing through the second pinhole 504, the reflected light beam 115 passes through the optical fiber 502. The optical fiber 502 enables the transmission of the collected reflected light beams 115 to the measurement channel spectrometers 124.

As an example, FIG. 5B is another embodiment of the collection system 120. The collection system 120 illustrated in FIG. 5B comprises a collection polarizer 512, a second pupil 524, a second off-axis parabolic mirror 522, and a fiber optic 520. The difference between the embodiment illustrated in FIG. 5A and the embodiment illustrated in FIG. 5B is the components that the reflected light beam 115 passes between before being directed out of the collection system 120. In the embodiment illustrated in FIG. 5B, the reflected light beam 115 passes through the collection polarizer 512 before passing through the second pupil 524. After, the reflected light beam 115 passes to the second off-axis parabolic mirror which directs the collected reflected light beam 115 into the fiber optic 520 to be sent to the measurement channel spectrometer 124.

Another example embodiment of the optical metrology system 100 of this disclosure is illustrated as the schematic diagram in FIG. 6. The only difference between the embodiment of optical metrology system 100 of FIG. 6 from the optical metrology system 100 of FIG. 1 is that the optical metrology system 100 of FIG. 6 comprises a single spectrometer 122 (as opposed to a plurality of spectrometers 122) with multiple inputs (one input for each of the plurality of collection systems 120), which comprises the measurement channel spectrometer 124 and the reference channel spectrometer 126. An advantage of embodiments that use a single light source 102 and a single spectrometer 122 is further cost reduction of the optical metrology system 100.

In an embodiment of the configuration illustrated in FIG. 6, the plurality of shutters 208 may be staggered in time such that only a single reflected light beam 115 is analyzed by the spectrometer 122 at a time. The system controller 128 may be aware of which shutter 208 was open when signals were received from the spectrometer 122 so that the system controller 128 may properly account for which substrate 116 the measured properties correspond to.

In another embodiment, the plurality of collected reflected light beams 115 from the plurality of collection systems 120 may be coupled to an optical switch (not shown) that is coupled to the measurement channel spectrometer 124. By using the optical switch, only a single process chamber's 110 collected reflected light beam 115 may be sent to the measurement channel spectrometer 124 to measure the properties of the reflected light beam 115 at a time. And by rotating through the various optical switch inputs over time, the single spectrometer 122 can provide measurements for each of the substrates 116 without using a plurality of spectrometers 122.

FIG. 7 is a flowchart of an etch monitoring method that uses the optical metrology system 100 of this disclosure to simultaneously monitor and stop a plurality of etch processes throughout a plurality of process chambers 110 when the end-points are detected, in an embodiment. At box 702, a single substrate of a plurality of substrates is loaded into each of a plurality of process chambers. In an embodiment, the substrates 116 may be loaded into a substrate holder 118, such as the substrate holder 118 illustrated in either FIG. 1 or FIG. 6.

In box 704, the plurality of substrates are processed within the plurality of process chambers. In an embodiment, the simultaneous processing of the plurality of substrates may be performing a plurality of etch processes across the plurality of substrates according to an etch recipe. In some embodiments, the etch recipe may be different for each substrate across the plurality of etch processes. In another embodiment, the etch recipe may be the same across the plurality of etch processes.

At box 706, an optical beam is generated by a light source. The generated optical beam may be generated by any light source suitable for generating an optical beam that may be reflected off of the surface of the plurality of substrates for monitoring the processing occurring in the plurality of process chambers. In some embodiments, the light source may be a laser driven plasma light source (LDLS). The optical beam may have an initial intensity that may be modified before being used for monitoring the plurality of substrates being processed.

In box 708, the optical beam is divided into a plurality of light beams. This may be accomplished in a variety of ways, such as the embodiments illustrated in FIGS. 2A-2C, or by the optical switch embodiment described above. The plurality of light beams is sent to the plurality of process chambers to illuminate an area of each of the plurality of substrates. In various embodiments, the optical beam may be further divided such that a plurality of reference light beams may be sent to a plurality of reference channel spectrometers. In those embodiments, the reference light beams may be used to compare with the reflected light beams from the surface of the substrates to determine features of the substrates.

At box 710, a property of each of the plurality of substrates is measured by reflecting one of the plurality of light beams off each of the plurality of substrates. In an embodiment, the property measured of each of the plurality of substrates may be physical features being etched, such as size and shape. In other embodiments, the property measured of each of the plurality of substrates may be the intensity of the plurality of reflected beams. In some embodiments, properties may be measured of each of the plurality of substrates, which comprise physical features and the intensity of the plurality of reflected beams. In various embodiments, the property, or properties, may be measured using a spectrometer that acquires a collected spectrum for each of the plurality of light beams reflected off each of the plurality of substrates.

And at box 712, using a controller (such as the system controller 128 of FIG. 1 and FIG. 6), the measured property, or properties, of each of the plurality of substrates are used to determine whether the substrate has reached an end-point of its processing, and then modifying the process accordingly.

Physical features may be determined using multiple methods from the collected spectrum. For example, physical features may be determined by referencing a library to match the detected spectrum with a pre-stored spectrum (such as the reference light beams mentioned above). In one embodiment, direct physical regression models may be used to obtain film thickness for un-patterned wafers as the substrates. Regression models may be used to measure critical dimensions (CDs) with simple patterns such as 2D lines.

In some embodiments, machine learning techniques (e.g., neural network, information fuzzy network) may be used. A supervised training method trains the relationship between initial and target end-point spectrum. During the training phase of the machine learning method, the spectrum from samples is collected. The properties associated with each sample may be obtained from CD metrology tools. Then, a model is trained using the collected data and the properties of each sample.

At the real-time application stage, that trained relationship is used to predict target point from initial spectrum of each substrate. Spectra collected during etch process are compared with that predicted spectrum to detect a target end-point for each substrate.

The determined properties of the plurality of substrates may be used in a manner of ways. In one case, the determined properties may be that the processing has not completed a step of the etch recipe, so the determined property would cause the method to continue processing the substrate without modifying the etch recipe. In another case, the determined properties may be that the processing has reached an end-point (for example, the etch cycle has etched a feature through the corresponding layer of a layer stack). In that case, the method would stop the processing, modify the etch recipe to the next step, and proceed with processing. The last case may be that the properties determined require a modification to the etch recipe to finish etching a corresponding feature to completion. In this last case, the method will modify the etch recipe and proceed with processing the same feature without moving on to the next step of processing.

In various embodiments, the properties determined by the method illustrated in FIG. 7 cause the processing of the substrate to be altered. The method illustrated in FIG. 7 determines properties of a plurality of substrates, simultaneously. As a result, the various processes occurring across the plurality of etch recipes may be modified and adjusted simultaneously in different ways. For example, one process chamber may have the processing adjusted to etch for a longer amount of time while a different process chamber may have the processing move to the next step of an associated etch recipe.

In certain embodiments, when monitoring a plurality of process chambers using the method described above, the same model may be used across the plurality of substrates. By calibrating the incident light beams used in the plurality of process chambers, the same model may be used in all of the plurality of process chambers. The ability to use the same model across the plurality of process chambers is another benefit of the optical metrology system of this disclosure. A calibration method for calibrating the optical metrology system of this disclosure is described next.

FIG. 8 is a flowchart of an optical metrology system calibration method that may be used to calibrate an optical metrology system 100 that simultaneously monitors a plurality of etch processes in a plurality of process chambers 110, in an embodiment. In box 802, a plurality of calibration wafers of known surface reflectance is loaded into a plurality of process chambers. The plurality of calibration wafers of know surface reflectance are loaded into the plurality of substrate holders 118 inside the plurality of process chambers 110 of FIG. 1 or FIG. 6, for example.

After loading the plurality of calibration wafers, an optical beam is generated by a light source at box 804. The optical beam is generated with a set intensity by the light source, and is initially unpolarized. In some embodiments, the light source may be a laser driven plasma light source (LDLS). After the optical beam is generated by the light source, the optical beam may pass through other optical equipment, which may further modify the optical beam before it may be used to illuminate an area of the surface of the calibration wafers of known surface reflectance.

Before being used to illuminate an area of the surface of the calibration wafers, at box 806 the optical beam is divided into a plurality of light beams. This may be accomplished with a variety of optical configurations, such as the embodiments illustrated in FIGS. 2A-2C, or by the optical switch embodiment described above. The plurality of light beams is sent to the plurality of process chambers to illuminate an area of each of the plurality of calibration wafers. In various embodiments, the optical beam may be further divided such that a plurality of reference light beams may be sent to a plurality of reference channel spectrometers. In those embodiments, the reference light beams may be used to compare with the reflected light beams from the surface of the substrates to determine features of the substrates.

In box 808, a property of each of the plurality of calibration wafers is measured by reflecting one of the plurality of light beams off each of the plurality of calibration wafers. In an embodiment, the property measured of each of the plurality of calibration wafers is the intensity of the reflected light beam. In that embodiment, the intensity may be measured using a spectrometer that acquires a collected spectrum for each of the plurality of light beams reflected off each of the plurality of calibration wafers. In another embodiment, the property measured of each of the plurality of calibration wafers may be the location of the illuminated area on the calibration wafers. In yet another embodiment, the property measured of each of the plurality of calibration wafers may be the size and shape of the illuminated area on the calibration wafers. In other embodiments, a set of properties, including the intensity, the size and shape of the illuminated area, and the location of the illuminated area of the calibration wafers, may be measured. The measured property, or properties, may then be communicated to a controller.

At box 810, the controller is used to determine whether the measured property of the calibration wafer is consistent with an intended value. For example, in an embodiment where the measured property is intensity, the controller may determine that adjustments in intensity of the incident light beams will make the measured property consistent with the intended value (where the intended value is some initial intensity). As another example, in an embodiment where the measured property is the reflectance of the calibration wafer, the measured reflectance may be compared with the known reflectance (where the know reflectance is serving as the intended value) to determine adjustments that would bring the incident light beams within tolerance of the known reflectance.

In box 812, a calibration recipe is prepared based on the determination made by the controller. The calibration recipe is used to adjust parameters of a light adjustment system so that the plurality of incident light beams are consistent with the intended value. The calibration recipe may also include instructions for modifying the location, size, and shape of the illuminated areas produced by reflecting the plurality of incident light beams off of the surface of substrates to be processed by the plurality of process chambers.

In an embodiment, the adjusted parameter of the light adjustment wheel may be a rotational angle of a filter wheel, which changes the intensity of the light beam that enters the process chamber. For example, the calibration recipe may contain information specific to each of the plurality of process chambers such that each chamber will have various configurations of the angles of each of the plurality of filter wheels such that each of the process chambers use light beams of the same intensity. In a similar embodiment, each process chamber may have components capable of adjusting the size of the cross-sectional area of the light beam entering the process chamber. In that embodiment, the calibration recipe may include settings for the components capable of adjusting the size of the cross-sectional area of the light beam for each of the plurality of process chambers such that the size, and shape of the illuminated areas on the substrates are the same across each process chamber.

In an embodiment, the calibration method of FIG. 8 may be performed regularly in set intervals of processing of wafer lots. For example, to ameliorate changes in size and shape of the illuminated area, or variations in intensity of the incident light beams, the optical metrology system may be calibrated using the calibration method above after every 24 wafers are processed. In other embodiments, the optical metrology system may be calibrated whenever the product being fabricated changes. In other embodiments, the optical metrology system may be calibrated multiple times throughout the processing of the same wafer lot (calibrated before 24 wafers have been processed). The optical metrology system may be calibrated as frequently as is beneficial to ensure consistency between processed wafers without reducing product fabrication rates.

As a result of using the calibration method to adjust the initial parameters of the plurality of light beams entering the plurality of process chambers such that each of the plurality of light beams have the same initial parameters, the same model may be used across the plurality of process chambers to determine features of the plurality of substrates being simultaneously processed. This is another benefit of the optical metrology system of this disclosure.

While embodiments of this application are discussed using etching as an example, various embodiments may also be applicable to deposition.

Example embodiments of the invention are described below. Other embodiments can also be understood from the entirety of the specification as well as the claims filed herein.

Example 1. A method for monitoring a plurality of process chambers, the method includes generating an optical beam at a light source. The method further includes dividing the optical beam into a plurality of light beams. The method further includes providing the plurality of light beams to the plurality of process chambers. And the method further includes measuring the plurality of light beams after being reflected within the plurality of process chambers.

Example 2. The method of example 1, the method further includes loading a first substrate into a first chamber of the plurality of process chamber, where the measuring includes measuring a reflected beam of the plurality of light beams after being reflected by a major surface of the first substrate. And the measuring further includes measuring a property of the first substrate from the measured reflected beam.

Example 3. The method of one of examples 1 or 2, the method further includes loading a plurality of substrates into the plurality of process chambers, and simultaneously processing the plurality of substrates, where the measuring is performed during the simultaneous processing.

Example 4. The method of one of examples 1 to 3, where the measuring includes collecting the reflected beam from the first substrate. The measuring further includes sensing an intensity of the reflected beam. And the measuring further includes, based on the intensity of the reflected beam, determining the property.

Example 5. The method of one of examples 1 to 4, the method further includes comparing the intensity of the reflected beam with a reference light beam, the reference light beam being one of the plurality of light beams obtained after dividing the optical beam.

Example 6. The method of one of examples 1 to 5, where the measuring includes measuring the plurality of light beams at the same time.

Example 7. The method of one of examples 1 to 6, where the measuring includes measuring the plurality of light beams at different times.

Example 8. The method of one of examples 1 to 7, where the measuring includes measuring each reflected beam of the plurality of light beams at a different spectrometer.

Example 9. The method of one of examples 1 to 8, where the measuring includes measuring each reflected beam of the plurality of light beams at a common spectrometer.

Example 10. The method of one of examples 1 to 9, the method further includes loading a plurality of substrates into the plurality of process chambers, and processing the plurality of substrates. And the method further includes determining a value of the property of each of the plurality of the substrates based on the measuring.

Example 11. The method of one of examples 1 to 10, the method further includes, based on the determined property, identifying one of the plurality of process chambers to be operating outside of a target process window. And the method further includes altering a process parameter for the process chamber identified as being operating outside of the target process window.

Example 12. A method includes dividing an optical beam into a plurality of light beams. The method further includes transmitting the plurality of light beams through a plurality of light adjustment systems in to a plurality of process chambers. The method further includes reflecting one of the plurality of light beams off each of a plurality of calibration wafers to measure a property of each of the plurality of calibration wafers, each of the plurality of calibration wafers having a known surface reflectance. The method further includes determining, in a controller, whether the property of each of the plurality of calibration wafers is within a process window. And the method further includes adjusting one or more of the plurality of light adjustment systems based on the determining.

Example 13. The method of example 12, where the determining includes comparing the reflected light beam of the plurality of light beams with a reference light beam, the reference light beam being formed by dividing the optical beam.

Example 14. The method of one of examples 12 or 13, further includes after the adjusting, processing a plurality of wafers within the plurality of process chambers. And the method further includes measuring a property of each of the plurality of wafers using an optical metrology system.

Example 15. The method of one of examples 12 to 14, where each of the plurality of light adjustment systems includes a shutter for modulating each of the plurality light beams, and a filter wheel for changing the intensity of each of the plurality of light beams.

Example 16. The method of one of examples 12 to 15, where the adjusting one or more of the plurality of light adjustment systems includes rotating the filter wheel of each of the plurality of light adjustment systems to change the intensity of each of the plurality of light beams based on the determining.

Example 17. The method of one of examples 12 to 16, where the property measured of each of the plurality of calibration wafers includes the intensity of each of the plurality of light beams.

Example 18. The method of one of examples 12 to 17, where the property measured of each of the plurality of calibration wafers includes the location, size, and shape of an illuminated area formed on each of the plurality of calibration wafers when each of the plurality of light beams reflects off each of the plurality of calibration wafers.

Example 19. An optical metrology system includes a light divider optically coupled to a light source, the light divider having a single optical input and a plurality of optical outputs. The system further includes illumination systems optically coupled to the light divider, each of the illumination systems optically coupled to one of the optical outputs and each of the illumination systems being associated with one of a plurality of process chambers. And the system further includes collection systems, each of the collection systems being associated with one of the plurality of process chambers, each of the collection systems being optically coupled to one of the illumination systems through the associated process chamber.

Example 20. The system of example 19, further includes optical filters coupled between the illumination systems and the light divider, and mechanical drive systems to position the optical filters in an optical path between the light divider and the illumination systems.

Example 21. The system of one of examples 19 or 20, further includes a plurality of spectrometers, each of the plurality of spectrometers being optically coupled to an output of one of the collection systems.

Example 22. The system of one of examples 19 to 21, further includes an optical switch including a plurality of optical inputs and a single optical output, where the plurality of optical inputs are optically coupled to each of the collection systems. And the system further includes a spectrometer optically coupled to the optical output of the optical switch.

Example 23. The system of one of examples 19 to 22, where the light divider includes an optical switch.

Example 24. The system of one of examples 19 to 23, where each of the optical filters include a shutter for modulating light beams produced by the light source and passed through the light divider. And each of the optical filters include a filter wheel for changing the intensity of light beams before they reach the illumination systems.

Example 25. The system of one of examples 19 to 24, further includes an optical cable to optically couple the light source to the plurality of process chambers.

Example 26. The system of one of examples 19 to 25, further includes a beam splitter and an off-axis parabolic mirror to optically couple the light source to the plurality of process chambers.

Example 27. The system of one of examples 19 to 26, further includes a parabolic mirror and a knife edge right angle prism mirror to optically couple the light source to the plurality of process chambers.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for monitoring a plurality of process chambers, the method comprising:
generating an optical beam at a light source;
dividing the optical beam into a plurality of light beams;
providing the plurality of light beams to the plurality of process chambers; and
measuring the plurality of light beams after being reflected within the plurality of process chambers.

2. The method of claim 1, further comprising:
loading a first substrate into a first chamber of the plurality of process chamber, wherein the measuring comprises measuring a reflected beam of the plurality of light beams after being reflected by a major surface of the first substrate; and
measuring a property of the first substrate from the measured reflected beam.

3. The method of claim 1, further comprising loading a plurality of substrates into the plurality of process chambers, and simultaneously processing the plurality of substrates, wherein the measuring is performed during the simultaneous processing.

4. The method of claim 2, wherein the measuring comprises:
collecting the reflected beam from the first substrate;
sensing an intensity of the reflected beam; and
based on the intensity of the reflected beam, determining the property.

5. The method of claim 4, further comprising:
comparing the intensity of the reflected beam with a reference light beam, the reference light beam being one of the plurality of light beams obtained after dividing the optical beam.

6. The method of claim 1, wherein the measuring comprises:
measuring each reflected beam of the plurality of light beams at a different spectrometer.

7. The method of claim 1, further comprising:
loading a plurality of substrates into the plurality of process chambers, and processing the plurality of substrates; and
determining a value of the property of each of the plurality of the substrates based on the measuring.

8. The method of claim 4, further comprising:
based on the determined property, identifying one of the plurality of process chambers to be operating outside of a target process window; and
altering a process parameter for the process chamber identified as being operating outside of the target process window.

9. A method comprising:
dividing an optical beam into a plurality of light beams;
transmitting the plurality of light beams through a plurality of light adjustment systems in to a plurality of process chambers;
reflecting one of the plurality of light beams off each of a plurality of calibration wafers to measure a property of each of the plurality of calibration wafers, each of the plurality of calibration wafers having a known surface reflectance;
determining, in a controller, whether the property of each of the plurality of calibration wafers is within a process window; and
adjusting one or more of the plurality of light adjustment systems based on the determining.

10. The method of claim 9, wherein the determining comprises comparing the reflected light beam of the plurality of light beams with a reference light beam, the reference light beam being formed by dividing the optical beam.

11. The method of claim 9, further comprising:
after the adjusting, processing a plurality of wafers within the plurality of process chambers; and
measuring a property of each of the plurality of wafers using an optical metrology system.

12. The method of claim 9, wherein each of the plurality of light adjustment systems comprise:
a shutter for modulating each of the plurality light beams; and
a filter wheel for changing the intensity of each of the plurality of light beams.

13. The method of claim 12, wherein the adjusting one or more of the plurality of light adjustment systems comprises rotating the filter wheel of each of the plurality of light adjustment systems to change the intensity of each of the plurality of light beams based on the determining.

14. The method of claim 9, wherein the property measured of each of the plurality of calibration wafers comprises the intensity of each of the plurality of light beams.

15. An optical metrology system comprising:
a light divider optically coupled to a light source, the light divider having a single optical input and a plurality of optical outputs;
illumination systems optically coupled to the light divider, each of the illumination systems optically coupled to one of the optical outputs and each of the illumination systems being associated with one of a plurality of process chambers; and
collection systems, each of the collection systems being associated with one of the plurality of process chambers, each of the collection systems being optically coupled to one of the illumination systems through the associated process chamber.

16. The system of claim 15, further comprising:
optical filters coupled between the illumination systems and the light divider; and
mechanical drive systems to position the optical filters in an optical path between the light divider and the illumination systems.

17. The system of claim 16, wherein each of the optical filters comprise:
a shutter for modulating light beams produced by the light source and passed through the light divider; and
a filter wheel for changing the intensity of light beams before they reach the illumination systems.

18. The system of claim 15, further comprising:
a plurality of spectrometers, each of the plurality of spectrometers being optically coupled to an output of one of the collection systems.

19. The system of claim 15, wherein the light divider comprises an optical switch.

20. The system of claim 15, further comprising an optical cable to optically couple the light source to the plurality of process chambers.

21. The system of claim 15, further comprising a beam splitter and an off-axis parabolic mirror to optically couple the light source to the plurality of process chambers.

22. The system of claim 15, further comprising a parabolic mirror and a knife edge right angle prism mirror to optically couple the light source to the plurality of process chambers.
